(19) United States
(12) Patent Application Publication
(10) Pub. No.: US 2007/0295530 A1
(43) Pub. Date: Dec. 27, 2007

(54) Coatings and methods for inhibiting tin whisker growth

(75) Inventors: Merrill M. Jackson, Tucson, AZ (US); David Humphrey, Tucson, AZ (US)

Correspondence Address: HONEYWELL INTERNATIONAL INC., 101 COLUMBIA ROAD, P O BOX 2245, MORRISTOWN, NJ, 07962-2245, US

(73) Assignee: Honeywell International, Inc.

(21) Appl. No.: 11/493,685

(22) Filed: Jul. 25, 2006

Related U.S. Application Data
(60) Provisional application No. 60/811,609, filed on Jun. 7, 2006.

(51) Int. Cl. H05K 1/00; C25D 7/06

(52) U.S. Cl. 174/250; 205/154; 205/164

(57) ABSTRACT

An electrical component includes a conductive substrate, a tin layer formed on the substrate, and a conformal coating formed on the tin layer to impede tin whisker growth. The conformal coating includes a polymer matrix, and particles that are dispersed about the matrix. The particles are either significantly harder than the polymer matrix, or are significantly softer than the polymer matrix.

### CROSS-REFERENCES TO RELATED APPLICATIONS

This application claims the benefit of U.S. Provisional Application No. 60/811,609, filed Jun. 7, 2006.

### TECHNICAL FIELD

The present invention relates to new or refurbished electronic assemblies or assembly components that may have a metal plating or finish, and more particularly to such assemblies or components having a tin plating or finish.

### BACKGROUND

Electronic assemblies or assembly components are often plated or finished with a metal. Printed wiring boards and electrical leads are just some examples of many components that typically have a metal finish. Perhaps the most abundant metal composition for a plating or a finish has been lead/tin (PbSn). However, laws and directives recently passed in several countries encourage or require the elimination of lead by those procuring, designing, building, or repairing electronic assemblies. The restriction of lead use has generated a transition by many piece part and board suppliers from PbSn surface finishes to lead-free finishes such as pure tin.

Tin finishes may be susceptible to spontaneous growth of single crystal structures known as tin whiskers. Tin whiskers are cylindrical, needle-like crystals that may grow either straight or kinked, and usually have a longitudinally striated surface. Growth rates for tin whiskers vary, although rates from 0.03 to 9 mm/yr have been reported. Interrelated factors including substrate materials, grain structure, plating chemistry, and plating thickness may influence growth rate. Although the whisker length depends on growth rate and sustained periods of growth, in experimental tests most measure between 0.5 and 5.0 mm although whiskers having a length of more than to 10 mm have been reported. The growth mechanisms for tin whiskers are largely unknown, although it is widely believed that whisker formation and growth are correlated with stresses such as localized compressive forces and environmental stresses on the tin plating or finish. Additional factors that may influence tin whisker growth include the materials constituting the substrate underlying the tin, and specifically a significant difference in the coefficients of thermal expansion between tin and the underlying substrate material since such a difference may stress the tin.

Tin whiskers may cause electrical failures ranging from performance degradation to short circuits. In some cases, the elongate structures have interfered with sensitive optical surfaces or the movement of micro-electromechanical systems (MEMS). Thus, tin whiskers are a potential reliability hazard. It is therefore desirable to provide materials and manufacturing procedures that mitigate the tendencies of pure tin and tin-containing solders, platings, and finishes to form tin whiskers. It is also desirable to provide such materials and methods that minimize the use of lead-containing compositions such as Pb/Sn solder.

### BRIEF SUMMARY

The present invention provides an electrical component, including a conductive substrate, a tin layer formed on the substrate, and a conformal coating formed on the tin layer to impede tin whisker growth. The conformal coating includes a polymer matrix, and particles that are dispersed about the matrix. The particles are either significantly harder than the polymer matrix, or are significantly softer than the polymer matrix.

The present invention also provides a method for impeding tin whisker growth from a tin plating or finish formed over an electrical component. The method includes the step of covering the tin plating or finish with a conformal coating comprising a polymer matrix having particles dispersed therein.

Other independent features and advantages of the preferred coatings and coating methods will become apparent from the following detailed description, taken in conjunction with the accompanying drawings which illustrate, by way of example, the principles of the invention.

### BRIEF DESCRIPTION OF THE DRAWINGS

FIG. 1 is a cross-sectional view of a tin finished electrical component having a conformal coating according to a first embodiment of the present invention;

FIG. 2 is a cross-sectional view of a tin finished electrical component having a conformal coating according to a second embodiment of the present invention;

FIG. 3 is a cross-sectional view of a tin finished electrical component having a conformal coating according to a third embodiment of the present invention; and

FIG. 4 is a flow diagram illustrating a method for forming a conformal coating on a tin finished electrical component according to an embodiment of the invention.

### DETAILED DESCRIPTION OF A PREFERRED EMBODIMENT

The following detailed description of the invention is merely exemplary in nature and is not intended to limit the invention or the application and uses of the invention. Furthermore, there is no intention to be bound by any theory presented in the preceding background of the invention or the following detailed description of the invention.

Electrical assemblies and components of the present invention have a tin plating or finish, and a conformal coating around the tin plating or finish. Growth of tin whiskers through the conformal coating is inhibited by including a growth disrupting material within the coating matrix material. The growth disrupting material is electrically nonconductive, and has significantly different hardness and/or modulus properties from the coating matrix material to cause growing tin whiskers to buckle and consequently either fail to exit the conformal coating or fail to grow a substantial distance from the conformal coating outer surface.

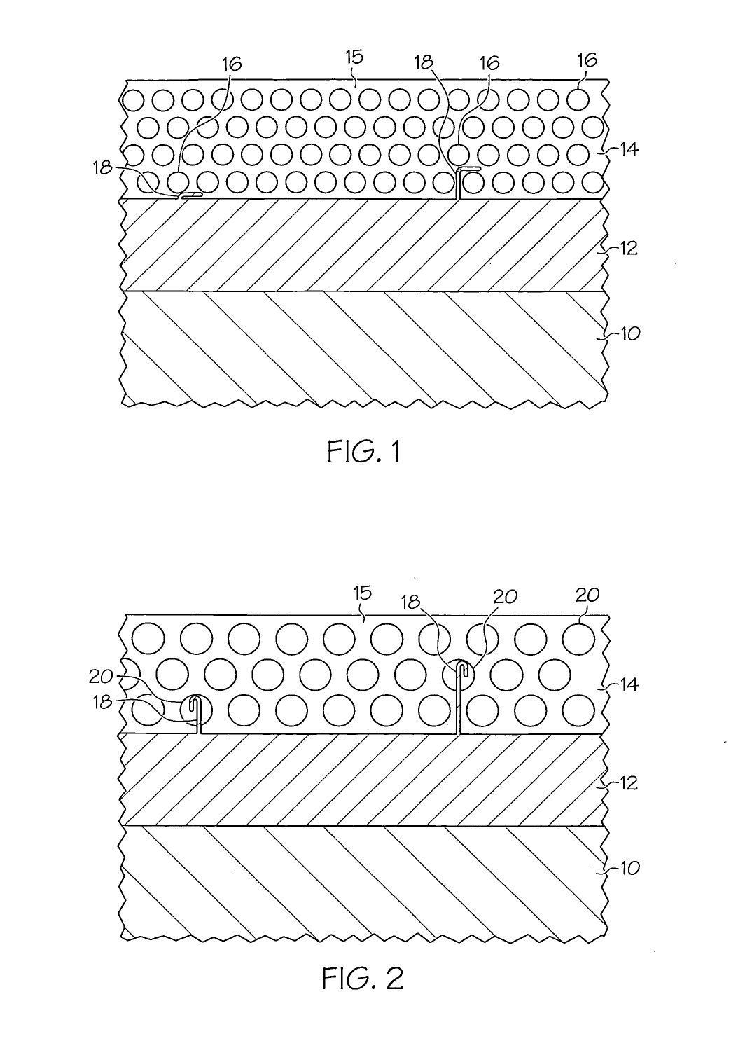

Turning now to FIG. 1, an electrical component substrate 10 having a tin finish 12 is depicted, with a conformal coating 14 formed over the tin finish 12. Just some examples of the substrate 10 include a circuit card assembly, a wiring board, one or more components printed on a wiring board, and one or more conductive leads. The conformal coating 14 includes a relatively soft matrix material. Exemplary conformal coatings are polymers including urethane, silicone, acrylic, paralenes, and polymers having an epoxy group in the molecule thereof. As previously discussed, conventional conformal coatings that consist of the same matrix materials may be somewhat susceptible to penetration by tin whiskers 18 as illustrated in FIG. 1. For this reason, the conformal coating 14 includes a dispersion of hard particles 16 against which the tin whiskers 18 will buckle instead of growing through the conformal coating 14.

The hard particles 16 are dispersed in a manner whereby the tin whiskers 18 have a high probability of contacting at least one particle 16 instead of growing through the conformal coating 14. For example, an exemplary coating 14 includes at least two layers of the hard particles 16, and preferably more than two particle layers. Even a conformal coating 14 having a thickness as small as 50 microns may include five to ten hard spherical particle layers, with the particles 16 having diameters ranging between 5 and 10 microns. Depending on the overall coating thickness, larger or smaller hard particles may be selected in order to provide a high probability for a tin whisker to collide with a hard spherical particle 16 before pushing through the conformal coating 14. For example, thicker coatings may include particles having an average diameter of up to 40 microns. As depicted in FIG. 1, one tin whisker 18 will collide with a particle 16 close to the tin finish 12 and will consequently buckle. Other tin whiskers may grow between particles disposed closest to the tin finish 12, but will eventually collide with a more outwardly disposed particle and will consequently buckle. Although the hard particles 16 are depicted as being in substantially organized layers in FIG. 1, the particles 16 may be randomly dispersed, and are preferably homogenously dispersed, at a sufficient concentration to provide a high probability for a tin whisker to collide with at least one particle 16.

According to the illustrated embodiment, the hard particles 16 have a substantially spherical in shape. Other conformal coatings may include hard particles having non-spherical shapes. For example, one or more different types of abrasive powder particles that are nonspherical may be included in the conformal coating 14.

The spherical particles 16 or other abrasive particles are sufficiently hard to cause a tin whisker to buckle instead of penetrating or displacing the particle. More particularly, the particles 16 are significantly harder than the conformal coating matrix 15. In an exemplary embodiment, the particles 16 are at least ten times harder than the coating matrix 15. Some exemplary particle materials include glasses, ceramics, and hard polymers. Buckling occurs as a tin whisker 18 collides with a particle 16, and the coating matrix 15 provides insufficient lateral support to allow the whisker 18 to displace or grow into the particle 16. Instead, the whisker 18 bends and grows in a different direction. Whether or not the angle of contact between the whisker 18 and the particle 16 is oblique, the particle 16 has a diameter that is between ten and forty times that of the whisker width and consequently presents an immovable barricade. Even if the whisker 18 grazes a particle 16 and just slightly bends rather than buckling, there is still a high probability that the whisker 18 will collide with another spherical particle instead of growing through the conformal coating 14. In addition to selecting a hard particle material, a significant differential between the matrix and particle hardnesses may be created by selecting a relatively soft conformal coating matrix material. For example, urethanes, silicone, and acrylics are exemplary relatively soft polymer materials that may be used as the coating matrix.

Turning now to FIG. 2, a second embodiment is illustrated in which, instead of incorporating hard particles, the conformal coating 14 includes a dispersion of soft spherical particles 20. More particularly, the spherical particles 20 are significantly softer than the conformal coating matrix 15. An exemplary coating 14 includes at least two layers of the soft spherical particles 20, and preferably more than two particle layers. The soft spherical particles 20 may be sized in a similar manner as the previously discussed hard spherical particles, and the conformal coating 14 may numerous particle layers depending on the overall coating thickness and the particle sizes. As with the previous embodiment, the soft spherical particles 20 are sized and dispersed in a manner whereby the tin whiskers 18 have a high probability of penetrating at least one particle 20 before growing through the conformal coating 14. More particularly, there should be at least one particle 20 present in any given cross-sectional slice of the coating. As depicted in FIG. 2, one tin whisker 18 will penetrate a particle 20 close to the tin finish 12, while other tin whiskers may grow between particles disposed closest to the tin finish 14, but will eventually penetrate a more outwardly disposed particle. The soft spherical particles 20 are depicted as being in substantially organized layers in FIG. 2, although the particles 20 may be randomly dispersed, and are preferably homogenously dispersed, at a sufficient concentration to provide a high probability for a tin whisker to penetrate at least one particle 20.

When a tin whisker 18 collides with a soft spherical particle 20, the whisker penetrates the particle 20 instead of buckling. The spherical particles 20 are sufficiently soft to be penetrable by the tin whisker 18, but to cause the tin whisker 18 to buckle instead of re-penetrating the conformal coating matrix 15 after traversing the particle 20. Just one exemplary soft particle material is expanded polystyrene. An important consideration for any selected soft particle material is that the particles 20 are significantly softer than the coating matrix 15. In an exemplary embodiment, the matrix material is at least ten times harder than the soft particle material. Buckling occurs as a tin whisker 18 collides with the coating matrix after traversing a particle 20, and the particle material provides insufficient lateral support to allow the whisker 18 to re-penetrate the coating matrix 15. Instead, the whisker 18 bends and grows in a different direction. In addition to selecting a soft particle material, a significant differential between the matrix and particle hardnesses may be created by selecting a relatively hard conformal coating matrix material. For example, epoxies and paralenes are exemplary relatively hard polymer materials that may be used as the coating matrix.

In order for the tin whisker 18 to buckle inside a soft spherical particle 20 without substantial resistance, the particles 20 preferably have a diameter that is at least ten times the tin whisker width. For example, if a tin whisker has a width of 3 microns, the soft spherical particle 20 should have a diameter of at least about 30 microns. Since tin whiskers typically have widths of up to about 5 microns, exemplary soft spherical particles 20 have average diameters of at least about 50 microns, although smaller particles may be selected if it is found that the tin whiskers are particularly thin growths. The tin whisker 18 becomes more bendable as it lengthens inside the spherical particle 20. If the tin whisker 18 is too short, the coating matrix 15 at the point where the tin whisker 18 entered the spherical particle will provide sufficient lateral support to enable the tin whisker 18 to re-penetrate the coating matrix 15 without buckling.

According to another embodiment, the concepts of both of the previously-described embodiments are combined by incorporating into the coating matrix hollow spherical particles with hard shell materials such as glasses, ceramics, and hard polymers. The hard outer shell material will usually cause the tin whiskers to buckle rather than displace or penetrate the shell. In addition, if a tin whisker does penetrate a particle, the lack of lateral support inside the hollow spherical particle will cause the tin whisker to buckle instead of re-penetrating the coating matrix when the tin whisker crosses the particle interior and collides with the hard shell material. In order for the tin whisker to buckle inside the hollow particles without substantial resistance, the particles preferably have an average diameter that is at least ten times the tin whisker width, as previously discussed.

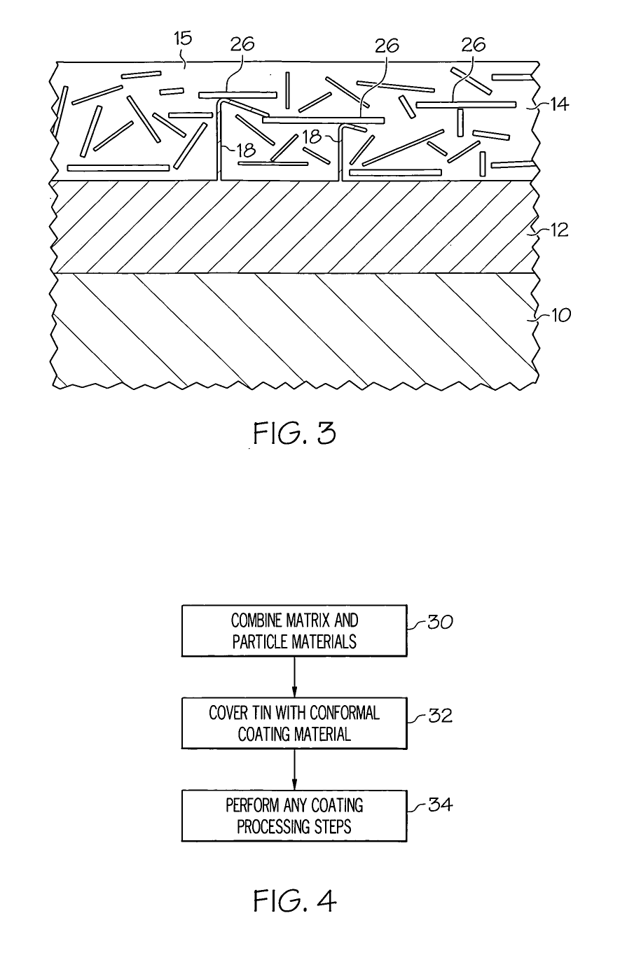

FIG. 3 is a cross-sectional view of a tin finished electrical component having an exemplary conformal coating according to a third embodiment of the present invention. Instead of hard or soft spherical particles, the conformal coating 14 includes hard particles having non-spherical shapes. For example, as depicted in FIG. 3, the conformal coating includes particles 26 having a substantially planar structure. Exemplary particle materials include materials whose crystal structures produce particles that are substantially planar in shape such as quartz, mica, and vermiculite.

As with the previous embodiments, the hard planar particles 26 are dispersed in a manner whereby the tin whiskers 18 have a high probability of contacting at least one particle 26 instead of growing through the conformal coating 14. More particularly, there should be at least one particle 26 present in any given cross-sectional slice of the coating. For example, an exemplary coating 14 includes at least two layers of the hard non-spherical particles 26, and preferably more than two particle layers. The non-spherical particles 26 are significantly harder than the conformal coating matrix 15 and consequently cause a tin whisker to buckle instead of penetrating or displacing the particle. Buckling occurs as a tin whisker 18 collides with a non-spherical particle 26, and the coating matrix 15 provides insufficient lateral support to allow the whisker 18 to displace or grow into the particle 26. Even if the whisker 18 grazes a non-spherical particle 16 and just slightly bends rather than buckling, there is still a high probability that the whisker 18 will collide with another non-spherical particle instead of growing through the conformal coating 14.

Turning now to FIG. 4, a flow diagram illustrates a general method for forming any of the previously-described conformal coatings. Coating matrix materials are combined with either hard or soft particles as step 30 to provide a coating material. The previous description provides exemplary materials for both the coating matrix and the hard or soft particles. The materials are selected and combined in a manner that corresponds to subsequent coating or processing steps. For example, if the coating is to be sprayed, dipped, deposited, or extruded, the materials may be combined in a mixing chamber or hopper that is in communication with a deposition nozzle or an extruder.

After providing the coating material, a tin plating or finish on an electrical substrate is covered with the coating material as step 32. Just a few exemplary methods for covering the tin with the coating material include extrusion, physical or chemical vapor deposition, dipping, and spraying. The covering method is selected based on the matrix and particle materials, and the electrical components being covered.

Yet another exemplary covering step includes dusting the tin plated or finished electrical component with a fine powder of just the hard or soft particles. Additional hard or soft particles may or may not be separately combined with the matrix material as step 30. Non-spherical particles such as mica are particularly good for providing a finely dusted layer. After dusting the electrical component with the fine powder of hard or soft particles, the particles are covered with the coating matrix material, which may or may not have additional hard or soft particles combined therewith.

After covering the tin plated or finished electrical component with the conformal coating material, any necessary processing steps are performed as step 34. Heating, humidifying, solvent addition, and radiation (i.e. UV radiation) are just some processing steps that may react or improve the conformal coating material. The processing steps may cause binder and/or other matrix materials to react and conform the coating to the coated surfaces. The processing steps may also enable the hard or soft particles to be more evenly dispersed.

The several methods and coating materials therefore provide electrical assemblies and components having a tin plating or finish, and a conformal coating around the tin plating or finish. The electrically nonconductive hard or soft particles are growth disrupting materials that inhibit growth of any tin whiskers through the conformal coating. While the invention has been described with reference to a preferred embodiment, it will be understood by those skilled in the art that various changes may be made and equivalents may be substituted for elements thereof without departing from the scope of the invention. In addition, many modifications may be made to adapt to a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

We claim:

1. An electrical component, comprising:
a conductive substrate;
a tin layer formed on the substrate; and
a conformal coating formed on the tin layer to impede tin whisker growth, the conformal coating comprising:
a polymer matrix, and
particles that are dispersed about, and are harder than, the polymer matrix.

2. The electrical component according to claim 1, wherein the particles are formed from a material selected from the group consisting of glasses, ceramics, and polymers.

3. The electrical component according to claim 1, wherein the particles are dispersed in a manner whereby at least one particle is present in any given cross-sectional slice of the conformal coating.

4. The electrical component according to claim 1, wherein the particles are at least ten times harder than the polymer matrix.

5. The electrical component according to claim 1, wherein the polymer matrix is selected from the group consisting of urethanes, silicone, acrylics, and polymers having an epoxy group in the molecule thereof.

6. The electrical component according to claim 1, wherein the particles are substantially planar in shape.

7. The electrical component according to claim 7, wherein the particles are formed from at least one material selected from the group consisting of quartz, mica, and vermiculite.

8. The electrical component according to claim 1, wherein the particles are substantially spherical in shape.

9. The electrical component according to claim 1, wherein the particles have a hollow core.

10. An electrical component, comprising:
a conductive substrate;
a tin layer formed on the substrate; and
a conformal coating formed on the tin layer to impede tin whisker growth, the conformal coating comprising:
a polymer matrix, and
particles that are dispersed about, and are softer than, the polymer matrix.

11. The electrical component according to claim 10, wherein the particles are formed from a material including expanded polystyrene.

12. The electrical component according to claim 10, wherein the particles are dispersed in a manner whereby at least one particle is present in any given cross-sectional slice of the conformal coating.

13. The electrical component according to claim 10, wherein the polymer matrix is at least ten times harder than the particles.

14. The electrical component according to claim 10, wherein the polymer matrix is selected from the group consisting of urethanes, silicone, acrylics, paralenes, and polymers having an epoxy group in the molecule thereof.

15. The electrical component according to claim 10, wherein the particles are substantially spherical in shape.

16. A method for impeding tin whisker growth from a tin plating or finish formed over an electrical component, the method comprising:
covering the tin plating or finish with a conformal coating comprising a polymer matrix having particles dispersed therein.

17. The method according to claim 16, wherein the particles are significantly harder than the polymer matrix.

18. The method according to claim 17, wherein the particles are formed from a material selected from the group consisting of glasses, ceramics, and polymers.

19. The method according to claim 16, wherein the particles are significantly softer than the polymer matrix.

20. The method according to claim 19, wherein the particles are formed from a material including expanded polystyrene.

21. The method according to claim 16, wherein the polymer matrix is selected from the group consisting of urethanes, silicone, acrylics, paralenes, and polymers having an epoxy group in the molecule thereof
